(19) United States
(12) Patent Application Publication
(10) Pub. No.: US 2002/0015855 A1
(43) Pub. Date: Feb. 7, 2002

(54) System and method for depositing high dielectric constant materials and compatible conductive materials

(76) Inventors: Talex Sajoto, San Jose, CA (US); Elaine Pao, Los Altos Hills, CA (US); Charles N. Dornfest, Fremont, CA (US); Jun Zhao, Cupertino, CA (US)

Correspondence Address: Patent Counsel, APPLIED MATERIALS, INC., P.O. Box 450A, Santa Clara, CA, 95052, US

(21) Appl. No.: 09/882,813

(22) Filed: Jun. 15, 2001

Related U.S. Application Data
(60) Provisional application No. 60/212,178, filed on Jun. 16, 2000.

(51) Int. Cl. C23C 14/32; C23C 16/00; B32B 15/00

(52) U.S. Cl. 428/639; 204/298.25; 204/192.12; 118/719; 118/715; 118/723 E; 427/248.1; 427/255.29; 428/544

(57) ABSTRACT

The present invention provides a system and method for depositing materials onto a substrate and preferably includes physical vapor deposition (PVD) and chemical vapor deposition (CVD) processing. In one aspect, a system is provided that deposits a stack of layers on a substrate comprising one or more nucleation layers, one or more conductive layers compatible with a high-dielectric-constant (HDC) material and one or more HDC layers in various sequences. The HDC material is useful in depositing thin metal-oxide films and ferroelectric films, as well as other films requiring vaporization of precursor liquids. The system allows PVD and CVD to occur within a centralized system to avoid contamination and reduce processing time. Further, different CVD layers can be deposited within the same CVD chamber. In one embodiment, multiple sets of vaporized gas passages and other gas passages can be formed through a gas manifold to allow mixing of multiple precursors near the endpoint of the flow path for control of the mixing regimes. The layer can be annealed to promote better adhesion and surface texture between adjoining layers.

### BACKGROUND OF THE INVENTION

1. Field of the Invention

The present invention relates to a method and an apparatus for depositing layers on substrates. Specifically, the invention relates to depositing a stack of one or more layers of conductive materials with one or more layers of high-dielectric-constant materials in semiconductor devices.

2. Background of the Related Art

High density semiconductor devices such as dynamic random-access memory (DRAM) integrated circuits are commonly used for storing data in a digital computer. DRAMs may contain over 16 million cells fabricated on a single crystal silicon chip, where each memory cell generally includes a single transistor connected to a miniature capacitor. Capacitor structures and materials that can store charge in smaller chip space are needed to facilitate construction of 256 MB, 1 GB and higher capacity DRAMs or other semiconductor devices with correspondingly smaller-sized memory cells or transistors. The size of vias, trenches and other features in such structures has decreased from having a size of 1 μm to having a size of about 0.25 μm to currently having a size less than 0.15 μm with an aspect ratio of greater than about 4:1. The size of the features coupled with a closer spacing of the features to create the high density structures has to some extent exceeded the capabilities of existing materials and processes. New technology and new materials are being investigated to reliably deposit materials into such structures.

High-dielectric-constant (HDC) materials (defined herein as having a dielectric constant greater than about 50) have been used successfully to form thin metal-oxide layers in such capacitor structures. Such HDC materials should be formable over an electrode and underlying structure without significant harm to the electrode and the underlying structure and exhibit low leakage current (i.e., the electrical current flowing from one electrode of the capacitor to the other electrode of the capacitor during operation of the capacitor) and consistent dielectric properties throughout the lifetime of the device. Further, corresponding conductive layers should be able to be deposited over the HDC materials and provide good interface characteristics such as good adhesion and low leakage current. Examples of HDC materials, herein including such materials as metal-oxide materials and ferroelectric materials, that are used in capacitor structures in microelectronic devices include lead lanthanium titanate (PLT), barium titanate, strontium titanate, barium strontium titanate (BST), lead zirconate titanate (PZT) and strontium bismuth tantalate (SBT). These materials are typically deposited by chemical vapor deposition (CVD) which is a process that involves flowing precursor gases into a chamber having a heated pedestal and a substrate disposed thereon and reacting the gases to deposit a layer on the substrate.

A liquid source BST CVD process entails atomizing a compound, vaporizing the atomized compound, depositing the vaporized compound on a heated substrate and annealing the deposited film. The process requires a high level of control over the liquid precursors and gases from the introduction of the precursor from an ampoule into a delivery system that includes vaporization and ultimate delivery of the compound to the surface of the substrate where the compound is deposited. Associated precursors have a narrow range for vaporization between decomposition at higher temperatures and condensation at lower temperatures. In .addition, the precursors tend to form deposits in the delivery lines and valves disposed throughout the system. CVD provides high deposition conformality in the small and/or high aspect ratio features.

Deposition of BST and other HDC materials also requires an oxidizer, such as oxygen. Current efforts have been directed to investigating oxidation resistant conductive materials, such as platinum, using CVD. However, the new conductive materials do not grow well over a silicon oxide substrate and peel or exhibit significant surface roughness. Further, the HDC materials, such as BST, exhibit a grain structure which is sensitive to the underlying grain structure of the prior conductive layer. Thus, a relative low surface roughness and properly oriented grain structure to deposit the HDC material thereon is desirable. The underlying layer should also have low film stress and good repeatability.

A typical solution would be to provide a barrier layer between the electrode material and the silicon dioxide that increases the adhesion between the electrode material and the silicon dioxide layers and provides a proper surface for the conductive material to deposit thereon. However, barrier layer materials and processes for conductive materials compatible with HDC processing are currently poorly defined and may not consistently produce a reliable structure. Further, barrier layer materials typically have a resistance that is several times higher than the conductive layer and, thus, the overall resistance of the structure is increased with use of a barrier layer.

Further, the apparatus and system typically used to deposit such HDC materials and associated layers provide limited abilities to mix the various precursors. In some proposed process regimes, the proper mixing and percentage of precursors in the mixed gases is not available or is inefficient, because of different vaporization temperatures and the required control of the precursors along the flow path.

Therefore, there remains a need for an apparatus and a method for manufacturing capacitors having high quality HDC materials between neighboring electrodes.

### SUMMARY OF THE INVENTION

The present invention provides an apparatus, method and system for depositing materials onto a substrate and preferably includes physical vapor deposition (PVD) and chemical vapor deposition (CVD) processing. In one aspect, a system is provided that deposits a stack of layers on the substrate comprising one or more nucleation layers, one or more conductive layers compatible with a high-dielectric-constant (HDC) material and one or more HDC layers in various sequences. For example, multiple sets of vaporized gas passages and other gas passages can be formed through a gas manifold to allow mixing of multiple precursors near the endpoint of the flow path for control of the mixing regimes.

In one embodiment, a nucleation layer is sputtered deposited on a substrate and a layer of a conductive material compatible with an HDC material can be deposited by CVD thereon. An HDC material can be deposited on the conductive material and, in some embodiments, can be deposited on a nucleation layer for the HDC material. An upper electrode layer of compatible conductive material can be deposited on the HDC material, forming a stack of layers on the substrate. The conductive HDC compatible material includes those materials having a conductance greater than about one mho and can be deposited adjacent an HDC material without substantial deterioration of either the HDC compatible material or the HDC material itself. The layer can then be annealed to increase the adhesion between the adjoining layers, provide a smoother surface texture, and promote preferred crystallographic orientation and size of grains of the layer. Other sequences can be deposited on the substrate and are exemplary.

An associated system and apparatus for depositing the layers is useful in depositing thin metal-oxide films and ferroelectric films, as well as other films requiring vaporization of precursor liquids. The system allows the PVD and CVD processing to occur within a centralized system to avoid contamination and reduce processing time. Further, the different CVD layers can be deposited within the same CVD chamber, while the PVD chamber can sputter deposit the target metal as well as oxides and nitrides thereof.

In one aspect, the invention provides a system for processing substrates, comprising a vacuum chamber, a PVD chamber in communication with the vacuum chamber, and a CVD having multiple vaporized gas precursor inlets, the CVD chamber being in communication with the vacuum chamber. In another aspect, the invention provides a chamber for processing substrates, comprising an enclosure having a top, bottom and sides, a substrate support disposed in the enclosure, and a gas manifold disposed above the substrate support, the gas manifold having at least two sets of passages, each set including an oxidizer passage and a vaporized gas passage. In a further aspect, the invention provides a method of depositing multiple layers on a substrate in a processing system, comprising depositing a nucleating layer on the substrate, depositing a conductive HDC compatible material on the nucleating layer by CVD and depositing an HDC material on the conductive HDC compatible material by CVD. In another aspect, the invention provides a substrate having layers formed thereon, comprising a nucleating layer deposited on the substrate, a CVD layer of a conductive HDC compatible material deposited on the nucleating layer and a CVD layer of an HDC material deposited on the conductive HDC compatible layer.

### BRIEF DESCRIPTION OF THE FIGURES

FIG. 1 is cross sectional view of a PVD chamber.

FIG. 2 is a perspective view of a CVD system.

FIG. 3 is a rearward perspective view of a CVD chamber.

FIG. 4 is cross sectional view of the CVD chamber.

FIG. 5 is a top view of a lid with a gas manifold of the CVD chamber.

FIG. 6 is a partial cross sectional view of the gas manifold shown in FIG. 5.

FIG. 7 is a top view of the gas manifold shown in FIG. 5.

FIG. 8 is a cross sectional view of the gas manifold shown in FIG. 5.

FIG. 9 is a top view of a lid with an alternative embodiment of the gas manifold.

FIG. 10 is a partial cross sectional view of the gas manifold shown in FIG. 9.

FIG. 11 is a schematic of a liquid delivery system.

FIG. 12 is a schematic view of a cluster tool system having multiple substrate processing chambers.

FIG. 13 is a schematic cross sectional view of a substrate having an exemplary stack of layers formed thereon.

### DETAILED DESCRIPTION OF THE INVENTION

The present invention generally provides an apparatus and method for depositing a conductive material compatible with HDC materials by providing a nucleation layer on a substrate, depositing conductive material on the nucleation layer and then depositing an HDC material on the conductive material. Another layer of compatible conductive material can be deposited on the HDC material. The nucleation layer can be deposited, for example, by physical vapor deposition (PVD) or ionized PVD, such as IMP-PVD or CVD. The material deposited on the nucleation layer can be deposited, for example, by CVD or electroplating processes.

The present invention also provides a system having a CVD chamber that can apply a variety of deposition materials to the substrate or layers thereon, including both the conductive HDC compatible material and the HDC material in situ, and an anneal chamber that can treat the deposited layers. In general, semiconductor devices that can be made with the present system are those characterized by having one or more layers of insulating, dielectric or electrode material deposited on a substrate. The system can also include a PVD chamber, an optional automated robotic transfer of substrates and onboard metrology sampling of the substrates. The system allows the PVD and CVD processing to occur within a centralized system to avoid contamination and reduce processing time. Further, the different CVD layers can be deposited within the same CVD chamber.

PVD Chamber

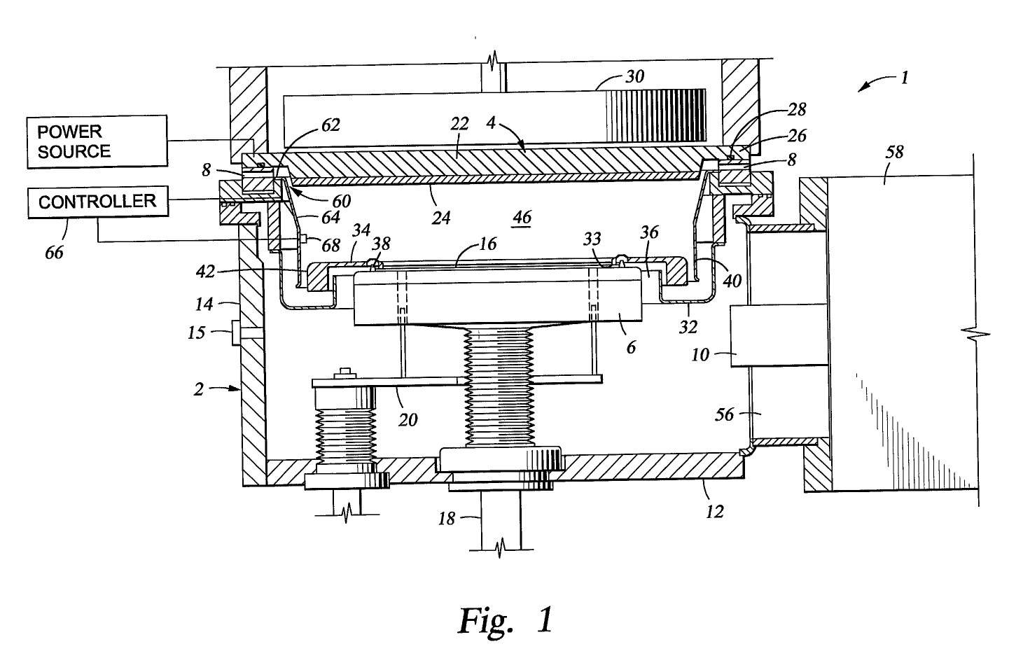

FIG. 1 is cross sectional view of a PVD chamber. The PVD chamber 1 generally comprises a chamber enclosure 2, a target 4, a substrate support 6, a gas inlet 8 and a gas exhaust 10. The chamber enclosure 2 includes a chamber bottom 12 and a chamber side wall 14. A slit valve 15 is disposed on a chamber side wall 14 to facilitate transfer of a substrate 16 into and out of the PVD chamber 1. The substrate support 6 is disposed on a substrate support lift assembly 18 through the chamber bottom 12. Typically, a temperature control element (not shown), such as a heater, is incorporated within the substrate support 6 to control the temperature of the substrate 16 during processing. Preferably, the substrate support 6 is made of stainless steel, and the temperature control element comprises a platinum/rhodium heater coil. The substrate support lift assembly 18 moves the substrate support 6 vertically between a substrate transfer position and a substrate processing position. A lift pin assembly 20 lifts the substrate 16 off the substrate support 6 to facilitate transfer of the substrate 16 between the chamber and a robot blade (not shown) used to transfer the substrate into and out of the chamber.

The target 4 is disposed in the top portion of the chamber enclosure 2. Preferably, the target 4 is positioned directly above the substrate support 6. The target 4 generally comprises a backing plate 22 supporting a plate 24 of sputterable material. Target materials used for forming conductive layers such as electrode layers can include platinum, ruthenium, iridium, as well as copper, titanium, aluminum and other metals. Target materials may also include combinations of these metals as well as other materials used for other PVD processes, such as reactive sputtering, wherein the sputtered material reacts with other materials or gases in the process cavity to form the deposited film. The backing plate 22 includes a flange portion 26 that is secured to the chamber enclosure 2. Preferably, a seal 28, such as an O-ring, is provided between the flange portion 26 of the backing plate 22 and the chamber enclosure 2 to establish and maintain a vacuum environment in the chamber during processing. A magnet assembly 30 is disposed above the backing plate 22 to provide magnetic field enhancement that attracts ions from the plasma toward the target sputtering surface to enhance sputtering of the target material.

A lower shield 32 is disposed in the chamber to shield the interior surfaces of the chamber enclosure 2 from deposition. The lower shield 32 extends from the upper portion of the chamber side wall 14 to a peripheral edge of the substrate support 6 in the processing position. A clamp ring 34 may be used and is removably disposed on an inner terminus 36 of the lower shield 32. When the substrate support 6 moves into the processing position, the inner terminus 36 surrounds the substrate support 6, and a peripheral portion 38 of the substrate 16 engages an inner terminus 33 of the clamp ring 34 and lifts the clamp ring 34 off the inner terminus 36 of the lower shield 32. The clamp ring 34 serves to clamp or hold the substrate 16 as well as shield the peripheral portion 38 of the substrate 16 during the deposition process. Alternatively, instead of a clamp ring 34, a shield cover ring (not shown) is disposed above an inner terminus of the lower shield. When the substrate support moves into the processing position, the inner terminus of the shield cover ring is positioned immediately above the peripheral portion of the substrate to shield the peripheral portion of the substrate from deposition.

Preferably, an upper shield 40 is disposed within an upper portion of the lower shield 132 and extends from the upper portion of the chamber side wall 14 to a peripheral edge 42 of the clamp ring 34. Preferably, the upper shield 40 comprises a material that is similar to the materials that comprise the target. The upper shield 40 is preferably a floating-ground upper shield that provides an increased ionization of the plasma compared to a grounded upper shield. The increased ionization provides more ions to impact the target 4 leading to a greater deposition rate because of the increased sputtering from the target 4. Alternatively, the upper shield 40 can be grounded during the deposition process.

A gas inlet 8 disposed at the top portion of the chamber enclosure 2 between the target 4 and the upper shield 40 introduces a processing gas into a process cavity 46. The process cavity 46 is defined by the target 4, the substrate 16 disposed on the substrate support 6 in the processing position and the upper shield 40. Typically, argon is introduced through the gas inlet 8 as the process gas source for the plasma. A gas exhaust 10 is disposed on the chamber side wall 14 to evacuate the chamber prior to the deposition process, as well as control the chamber pressure during the deposition process. Preferably, the gas exhaust 10 includes an exhaust valve 56 and an exhaust pump 58. The exhaust valve 56 controls the conductance between the interior of the chamber 1 and the exhaust pump 58.

To supply a bias to the target 4, a power source 52 is electrically connected to the target 4. The power source 52 may include an RF generator and an RF matching network coupled to the target 4. The power source 52 supplies the energy to the process cavity to strike and maintain a plasma of the processing gas in the process cavity during the deposition process.

A gas exhaust 10 is disposed on the chamber side wall 14 to evacuate the chamber prior to the deposition process, as well as control the chamber pressure during the deposition process. Preferably, the gas exhaust 10 includes an exhaust valve 56 and an exhaust pump 58. The exhaust valve 56 controls the conductance between the interior of the chamber 1 and the exhaust pump 58. The exhaust pump 58 preferably comprises a turbomolecular pump in conjunction with a cryopump to minimize the pump down time of the chamber. Alternatively, the exhaust pump 58 comprises a low pressure, a high pressure pump or a combination of low pressure and high pressure pumps.

Other types of sputtering can be used, such as an IMP-PVD process using an IMP Vectra™ chamber, available from Applied Materials, Inc. of Santa Clara, Calif. The IMP chamber additionally contains power supply coupled to the substrate to create a bias and a coil disposed between the target and the substrate, the coil being coupled to a third power supply. The coil is used to densify the plasma and the biased substrate to attract the sputtered particles in a substantially perpendicular direction to the substrate surface.

The CVD System and Chamber

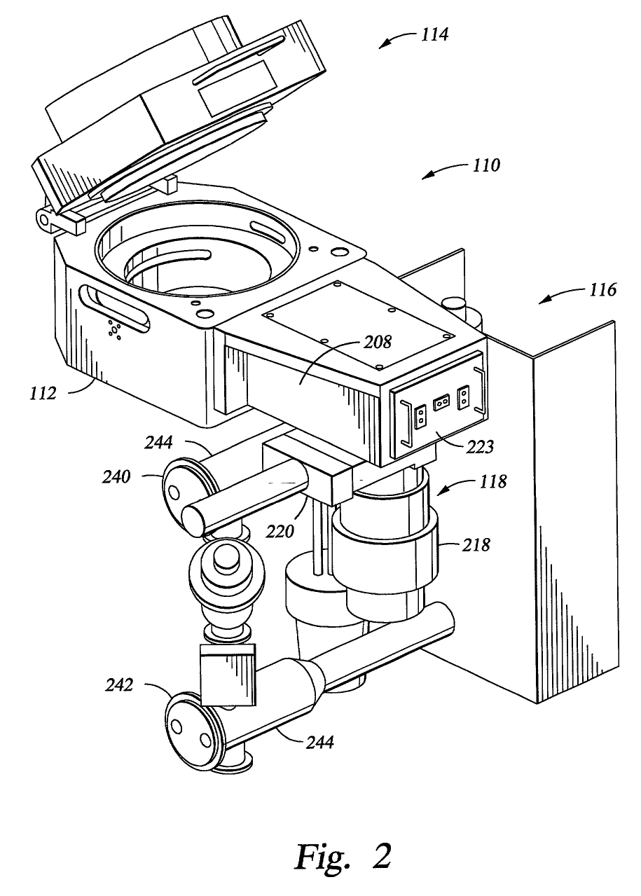

FIG. 2 is a perspective view of a CVD system 110. The system 110 generally includes a chamber body 112, a heated lid assembly 114, an integrated vaporizer module 116 and an exhaust/pumping system 118. Not shown in this figure, but a feature of the invention, is a liquid delivery system for supplying the various liquid precursors to the vaporizer module. The size and dimensions of the system are dictated by the size and shape of the workpiece on which processes of the present invention are performed. A chamber adapted to process a circular substrate, such as a 200 mm silicon wafer, will be described herein.

The system is able to deposit a variety of materials without necessitating transferring the substrate between chambers, that is, the chamber can deposit the various materials in situ. For example, the CVD system described herein can preferably be used to deposit both the bulk conductive material on the nucleation layer and the HDC material. The inventors have recognized that deposition layer uniformity can be enhanced in depositing HDC and related materials, and system maintenance can be reduced, if substantially all of the system components (other than the substrate and substrate heater) which “see” the process chemistry are substantially maintained at an ideal isothermal system temperature (e.g., 270° C. for BST). The deposition chamber incorporates several active and passive thermal control systems, including features for minimizing temperature gradients that can be created as a result of the relatively high temperature of the substrate and the substrate support member. The deposition chamber also includes thermal control features which serve to protect a main chamber seal by cooling it below the ideal isothermal system temperature. Other similar thermal control features maintain at a relatively safe temperature a cover enclosing the chamber lid to prevent burn injuries. Cooling is achieved without inducing significant temperature fluctuations and gradients in the system components exposed to the system chemistry and without excessive cooling and heating power losses.

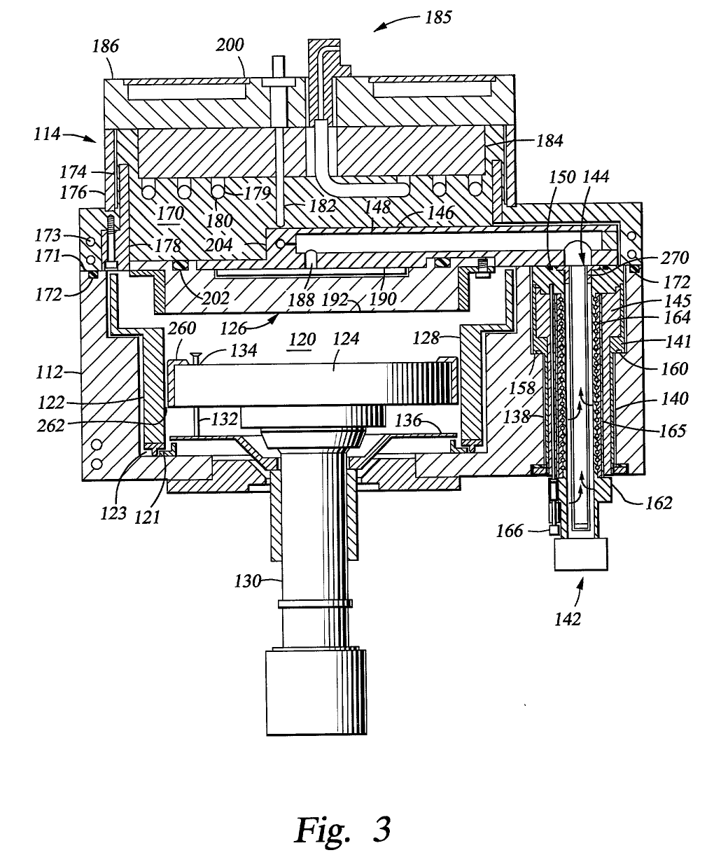

FIG. 3 is a cross sectional view of one embodiment of a deposition chamber showing the chamber body 112 supporting a heated lid assembly 114. The chamber body 112 defines an inner annular processing region 120 defined on the perimeter by an inner wall 122. A substrate support member 124 extends through the bottom of the chamber and defines the lower end of the processing region 120. A gas distribution plate 126 mounted on the lid forms the upper limit of the processing region 120. The chamber body 112 and the lid assembly 114 are preferably made of a rigid material such as aluminum, stainless steel or combinations thereof. The chamber body 112 also defines a pumping port for purging the remains of the deposition vapor once the vapor has been delivered over the substrate. A generally U-shaped passage surrounding the gas distribution assembly forms a pumping channel through which gases are drawn into the exhaust system.

The substrate support member 124 may comprise a metal, e.g., aluminum, with a resistive heating element attached thereto or embedded therein. Alternatively, the support member may comprise a ceramic block and embedded ground plate which generates heat when subjected to RF energy emitted by an adjacent electrode. A suitable substrate support member 124, typically known as a pedestal, and related lift assembly is shown and described in co-pending U.S. patent application Ser. No. 08/892,612 entitled “Improved Self Aligning Lift Mechanism,” filed on Jul. 14, 1997, and is incorporated by reference herein. This substrate support member is available from Applied Materials, Inc. of Santa Clara, Calif. under the model name CxZ™ Heater.

The substrate support member generally is movable up and down on a central elevator shaft 130 to move a substrate between a deposition position adjacent the gas distribution plate 126 and a substrate insertion/removal position below a slit valve formed through the chamber body. The entry point of the shaft into the chamber is sealed with a collapsible bellows (not shown). The substrate is lifted from or placed on a robot blade by a set of lifting pins 132 that are slidably retained in a set of four passageways 134 extending through the substrate support member 124. Directly below each of the pins is a lifting plate 136 which moves the pins vertically within the chamber to allow a substrate to be lifted off or placed on a robot blade which is moved into the chamber through the slit valve opening (not shown).

The chamber body 112 defines one or more passages 138 for receiving a heated gas delivery feedthrough 140 having an inlet 142 and an outlet 144 to deliver one or more precursor gases into the gas distribution plate 126 mounted on the lid assembly 114. The passage 138 defines an upper and a lower end of differing diameters to form a shoulder 158 where the upper and lower ends meet. The gas outlet 144 is fluidicly connected to a mixing gas manifold 146 which includes at least a first gas passage 148 to deliver a gas(es) into the gas distribution plate 126. A seal 150, preferably made of TEFLON® with a stainless steel c-spring, is located around the outlet 144 on the upper chamber wall to provide a sealing connection between the gas delivery feedthrough 140 and the gas manifold 146.

The feedthrough preferably includes an outer conduit 141 and an inner conduit 145 disposed within the outer conduit. The outer conduit includes a mounting shoulder 143 which is mounted on shoulder 158 of the passage. The outer conduit also includes a lower end having threads thereon for receiving a lock nut to secure the feedthrough in a sealing position within the passage 138 against the shoulder 158 and seal 150. The inner conduit 145 defines an upper mounting surface 149 for forming a seal with the lid assembly at seal 150 and also includes a flange 162 on its lower end for mating with the bottom of the chamber body. A cable type heater 164, or other suitable heater, is disposed in intimate contact with the inner conduit of the feedthrough to heat the feedthrough to a desired temperature. A radiation shield 165 is disposed over the heater to prevent thermal radiation from heating the outer conduit 141. A power lead (not shown) extends from the lower end of the feedthrough and is connected to a suitable power source to heat the feedthrough. A thermocouple 166 is inserted or otherwise disposed in the heated gas delivery feedthrough 140 to monitor the temperature thereof. The feedthrough is mounted in the passage and secured therein using a screw type connector or other suitable connector.

The upper wall 147 of the outer conduit 141 is thinned and sized to define a gap between its outer surface and the inner wall of the chamber body to provide a heat choke adjacent the seal 150. Seal 150 is preferably a hot O-ring that can withstand temperatures of about 300° C. The thin wall minimizes heat conduction down to the shoulder 158 to protect seal 150. By minimizing heat conduction, less power is required to heat the feedthrough. Additionally, less thermal mass provides better thermal control and faster response for the feedback control. Still further, the heat choke on the outer conduit reduces heat loss from the mixing gas manifold 146 which is directly connected to the insert and which is heated by the lid body. The reduction in heat loss helps avoid generation of cold spots along the path of the vaporized gas.

A filter 270 can be disposed in the feedthrough 140 between the inlet 142 and the outlet 144. The filter 270 preferably comprises a cylindrical hollow member, such as a tube, having a porosity sized to purify the precursor gas flow through the feedthrough prior to the gases entering the gas manifold 146. Additionally, the porosity reduces the entry of non-vaporized liquid precursor materials. The filter material can be stainless steel or other materials that are non-reactive with the precursor gases, such as titanium, nickel, Hastalloy®, aluminum, aluminum oxide, barium strontium titanate, aluminum nitride, silicon carbide or combinations thereof. A preferable porosity through the filter material can be 100 μm (microns) or less, preferably about 5 to about 20 μm and most preferably about 10 μm. The porosity can be varied depending on the precursor components, desired flow rate and pressure drop, useful life of the filter, and cleanliness of the system. A porosity of about 10 μm is a practical balance between useful life and adequate filtration for the processing of BST and other HDC or HDC compatible materials. The porosities can vary depending on the level of filtration desired, the precursor and other components, and location in the vaporizer and system.

Removable deposition chamber liners (which can be used at a number of different locations) facilitate periodic cleaning of the deposition chamber. Preferably, a liner includes an integral or functionally integral (i.e., assembled from one or more components as attached or overlapping units) generally chamber liner 128 that covers upper chamber surfaces adjacent the substrate support member 124 and a bottom liner 121 covers the lower chamber wall surfaces below substrate support member. The liner material may be made of a metal, e.g., stainless steel or aluminum, a ceramic material (e.g., Al₂O₃) or quartz, and can be equipped with an active PID controlled heating element which maintains the liner walls substantially at the optimum isothermal system temperature to inhibit both condensation and decomposition of gas vapor on the chamber surfaces. The material from which the liner is made preferably demonstrates chemical resistance to halogens and halogenated in situ cleaning compounds, and is preferably not adversely affected by, nor adversely affects, the process chemistry.

A chamber liner 128 is preferably disposed adjacent the inner wall 122 of the chamber to provide a removable surface within the chamber which can be easily cleaned and/or replaced. The liner 128 is supported in the chamber on supports 123, preferably three, which are equally spaced around the lower surface of the liner. The supports 123 are sized to minimize the contact area between the chamber liner 128 and the chamber body and thereby minimize heat conduction between the liner and the chamber body. In one embodiment, the liner is heated by radiation from the heated lid and the heated substrate support member. This embodiment is referred to as a passive floating liner. Alternatively, the liner may also include a resistive heater (not shown), or other suitable heater, disposed therein so that it can be actively heated and maintained at an ideal isothermal temperature.

A sealing edge ring 260 is disposed in the chamber and supported on the substrate support member 124 to contact and overlap a circumferential edge of the substrate support member 124. A circumferential rib can be provided on the underside of the ring in order to maintain the ring in an aligned position. The edge ring serves to close-off the annular space 262 between the liner 128 and the substrate support member 124 and, thereby, substantially reduce the amount of deposition vapor which flows into the lower part of the deposition chamber. In addition, the edge ring acts as a radiation shield. The outer circumferential portion of the gas distribution plate 126 typically extends beyond the diameter of the substrate. The edge ring 260 protects this outer part of the gas distribution plate 126 from heat directly radiated by the substrate support member. The edge ring 260 is preferably made of a material having a thermal coefficient of expansion similar to that of the deposition material to reduce the possibility of particle generation due to flaking during thermal cycling. In the case of BST, one such edge ring material is titanium.

The lid assembly 114 preferably comprises a main body 170 machined or otherwise formed of a metal having a high thermal conductivity, e.g., aluminum. The main lid body defines an annular channel 174 formed around its perimeter to define a thin outer wall 176. A support ring 178, preferably made of stainless steel or other thermal insulator, is disposed in the channel to provide structural support for the lid and to prevent thermal conduction to the outer wall 176. The thin outer wall of the body member provides a thermal choke for the base 171 of the lid which is sealed to the chamber body during processing at the seal 172, such as an O-ring seal. The seal 172 is positioned at a circumferential interface of the chamber body 112 and the lid assembly to maintain a hermetic and vacuum tight seal of the chamber. In order to actively cool the seal, one or more cooling channels 173 are preferably disposed in the lower lip of the outer wall 176. A heat exchange fluid (e.g., water, ethylene glycol, silicone oil, etc.) circulates through the channel to remove heat at the seal.

The thermal choke provided by the thin outer wall 176 isolates the seal 172 between chamber lid assembly 114 and the chamber body 112 from the heat generated by heating elements 180 disposed in the lid. The heat choke provides thermal protection of the seal 172 by allowing localized active cooling within the channel on top of the O-ring 172, without inducing significant detrimental cooling effects on the other system components. The thin wall 176 presents an effective thermal barrier between the heating elements and the O-ring due to its small cross-sectional area (A) and long length (I).

The upper surface of the main lid body 170 defines a plurality of annular recesses 179, such as spiral grooves, for receipt of a heating element 180 therein. In a preferred embodiment, a heater with a power output of about 6200 W is used. However, the amount of power will vary depending on the lid design and geometry, including material composition of the lid, and the process temperature. Power is delivered to the heating elements through a feedthrough 185 disposed in the lid. The heater is preferably controlled with conventional PID feedback control, based on signals received from a thermocouple 182 positioned or otherwise disposed in the lid. An annular plate 184 serving as a heat shield is mounted on the top of the heating elements. Preferably, the plate 184 is brazed to the lid body to form an integral part of the lid body. A water cooled cover plate 186 is disposed on or over the plate 184 to provide a controlled mechanism for pulling heat out of the lid for active feedback temperature control.

A cooling channel 200 is preferably formed in top cover plate 86 of the lid assembly 114. Cooling channel 200 removes heat from the lid. In addition, a thermal choke gap, preferably about 25 mils, is used to control the amount of heat removed from the lid during cooling. During deposition of a material such as BST, the substrate will be heated by the substrate support member to a temperature of over 400° C. Heat from the substrate and the substrate support member will radiate onto the gas distribution plate 126 thereby tending to increase its temperature above the optimum isothermal system temperature. By increasing the thermal conduction or transfer between the lid and the gas distribution plate 126, the substrate and substrate support member induced temperature gradients and fluctuations can be reduced. In order to improve heat conductivity between the lid and the gas distribution plate 126, an inert gas (e.g., helium, hydrogen, etc.) is circulated about the annular interface of these elements. The inert gas is introduced into channel 202, which may be circular, spiral or other shape, disposed in the lid. The channel can be formed in the mating annular surface(s) of the gas distribution plate 126 and the main lid body 170 and/or in the cover plate 186. The inert gas can be introduced from the top through the cooling plate or through the bottom of the chamber via a feedthrough connected to the gas manifold. Gas pressure in the channels can be maintained within the range from about 1 Torr to about 100 Torr, preferably within the range of about 1 Torr to about 20 Torr. Due to its high thermal conductivity, the circulating inert gas can improve heat transfer between the lid assembly 114 and the gas distribution plate 126.

The lid assembly, including the heating element, is configured to maintain the vapor inlet passageway and gas distribution plate at an isothermal system temperature, e.g., 270° C. 5° for BST. Passive and active cooling elements are used to maintain the top cover of the lid, and the seal 172 positioned between the chamber body and the lid assembly, at a substantially lower temperature, e.g., 100° C. or lower.

The mixing gas manifold 146 includes a central opening 188 which delivers the gases to a blocker plate 190 to initially disperse or distribute the gas(es) over a large area above a face plate 192. Each of the blocker plate and the face plate have a plurality of holes formed therethrough which evenly disperse the gas over the area of the plates 190, 192 and together form the gas distribution plate 126. The face plate 192 delivers the gas uniformly over the area of a substrate positioned on the substrate support member 124. The gas distribution plate 126 and the mixing gas manifold 146 are preferably made of aluminum and are sufficiently thick to allow heat transfer from the gas distribution plate to the temperature controlled lid assembly 114.

With respect to the gas distribution plate assembly, the use of a conventional thin blocker plate 190 with a relatively thicker face plate 192 also serves as a thermal control system. The mixing gas manifold 146 serves as a heated mass whose heat capacity and high thermal conductivity act as a source of thermal inertia resisting temperature variations from the center of gas distribution plate to its periphery. The gas mixing manifold 146 also avoids the effects of gas “channeling” through the material of the plate for providing a more even distribution of gas volume across the substrate surface. While the gas distribution plate is preferably made of aluminum, another thermally conductive material may also be used.

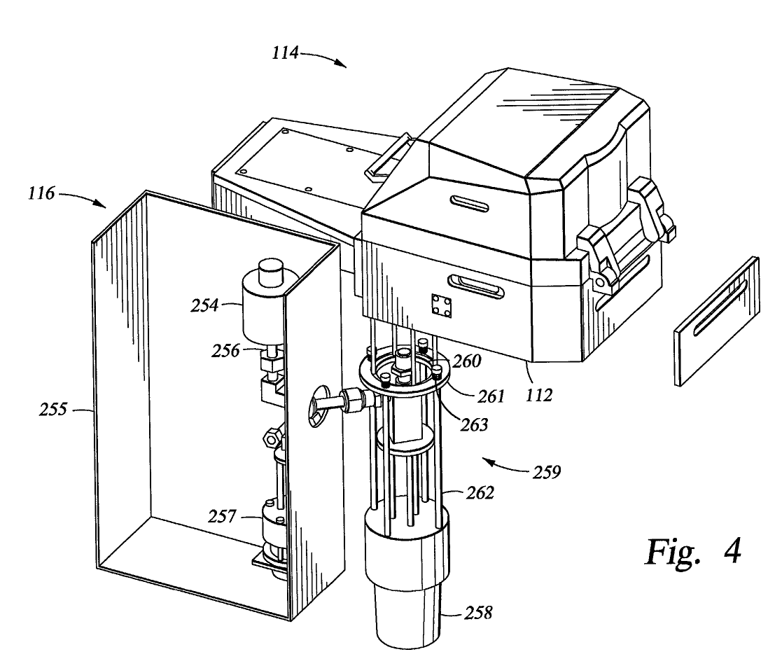

FIG. 4 is a perspective view showing the vaporizing module 116 mounted adjacent to the chamber 112. A vaporizer 254 is mounted in a vaporizer cabinet 255 and includes an outlet line 256 connected to the inlet into the chamber. Disposed along the outlet line 256 is a first valve 257 which is connected in turn to a bypass line (not shown) extending out through the back of the cabinet 255 and is connected to the exhaust system by a conduit in which the cold trap 242 is disposed (see FIG. 2). The bypass line is adapted to deliver both vaporized gas as well as liquid solvent into a cold trap disposed downstream from the valve in preparation of delivering vaporized gas to the chamber or during cleaning of the system. This valve controls delivery of the vaporized material to the chamber or through the cold trap in the exhaust system. A second valve 258 is disposed downstream from the first valve to selectively deliver the vaporized gas into the chamber. The second valve is mounted to the lower portion of the chamber via a rod and washer assembly 259. This assembly enables adjustment of the delivery line as well as the valve in relation to the chamber. The mount generally includes first and second rings 260, 261, respectively, one disposed in the other, to allow rotatable adjustment of an second valve 258 and the delivery line. The second valve 258 is mounted to the second ring 261 via a plurality of rods 262 (four shown here) which are mounted from the ring and include a spring 263 disposed above the upper portion of the rod and the second ring 261. The two rings 260, 261 enable rotation of the assembly while the spring and rod arrangement allow vertical adjustment of the assembly to ensure proper alignment of the gas feed line 256 into the chamber through the feedthrough 140, shown in FIG. 3. In general, the suspension apparatus provides automatic compensation for thermal expansion/contraction to maintain vacuum seals without the mechanical and thermal stress.

The vaporizer 254 contains a nozzle and a preferably a plurality of heated vaporizing surfaces therein. The nozzle sprays precursor liquids onto a heated first vaporizing element that vaporizes the sprayed droplets. A conduit surrounds the nozzle to allow inert gas to be flown axially adjacent an exterior surface of a nozzle tip to minimize wicking of the sprayed liquids. Additionally, the vaporizer contains a port for flowing carrier gas into the vaporizer. The vaporizing elements have a porosity between about 5 μm to about 100 μm that allows the vaporized liquid to flow therethrough as the vaporized fluid is filtered. Additional vaporizing elements can surround the first vaporizing element and further filter the vaporized fluids before exiting the vaporizer 254. The vaporizer 254 is described in more detail in copending application, U.S. patent application Ser. No. 09/467,296, entitled “High Temperature Filter For Cvd Apparatus”, filed on Dec. 17, 1999 and is incorporated by reference herein. An additional embodiment of a vaporizer is described in more detail in U.S. patent application Ser. No. 09/052,767, entitled “Vaporization Apparatus And Process”, filed on Mar. 31, 1998 and is incorporated by reference herein.

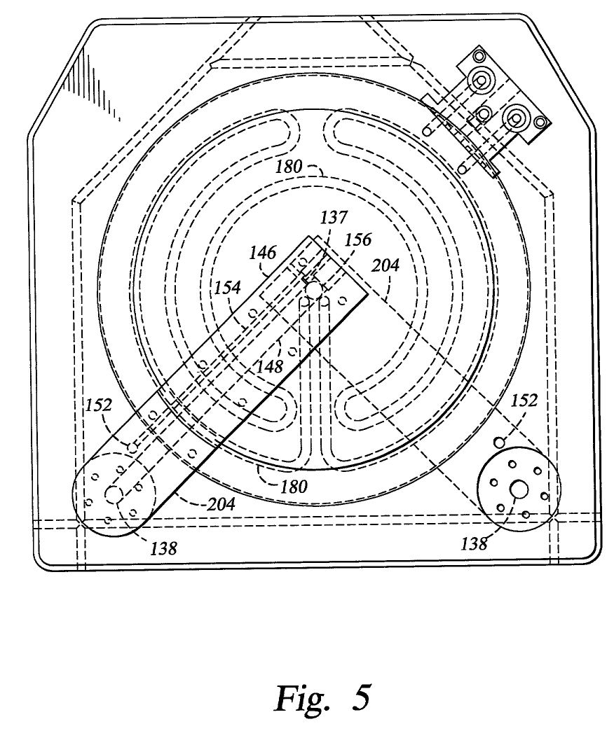

FIG. 5 is a top view of a chamber lid showing the heating element 180 and the mixing gas manifold 146. The lower surface of the lid body defines one or more channels 204 for mounting a gas manifold 146. The dashed line indicates that the gas manifold 146 can be mounted in at least two positions on the chamber. One or more oxidizer gas passages 152, similar to passage 138, are also formed in the chamber body 112 adjacent the passage 138 for receiving an oxidizer gas delivery feedthrough which can be heated if desired to deliver one or more oxidizer gases through the chamber wall to the mixing gas manifold 146. A gas passage 154 is formed in the mixing gas manifold 146 to deliver the oxidizer gas to a gas outlet 156, which provides a mixing point, located in the gas manifold adjacent the entry port into the gas distribution plate 126. A restrictive gas passage 137 connects the oxidizer gas passage 154 to the vaporized gas passage 148, such as near or at the end of each passage, to provide high velocity delivery as well as mixing of the gas mixture upstream from the gas distribution plate 126.

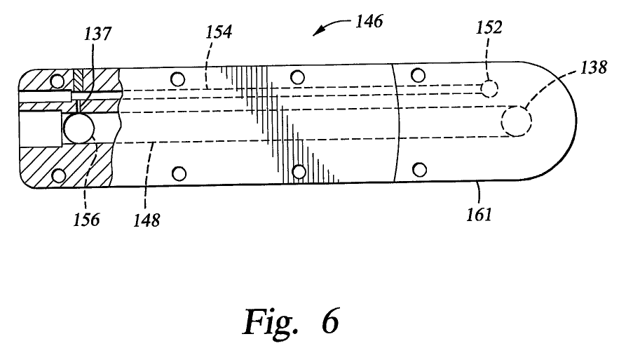

FIG. 6 is a partial cross sectional view of a gas manifold 146. The gas manifold 146 includes a gas delivery block 161 which defines one or more gas passages 148, 154 therein having one or more gas inlets 138, 152 on one end and a gas outlet 156 on the other end. The gas outlet 156 serves as a gas inlet of the gas distribution plate 126. A vaporized first gas passage 148 and an oxidizer gas passage 154 extend at least partially along the length of the gas manifold from the gas inlets to the gas outlet. A restrictive gas passage 137 is disposed between the vaporized first gas passage 148 and the oxidizer gas passage 154 to optimally mix and deliver the oxidizer gas into the vaporized gas passage at a relatively high velocity to assist in mixing of the gases. The mixed gases are delivered through the gas outlet 156 and to the blocker plate and face plate. Alternatively or additionally, a second set of a vaporized gas passage and an oxidizer gas passage, a carrier gas passage or a cleaning gas passage (to deliver a cleaning gas species from a remote plasma source) may also be provided through the chamber wall to deliver these gases to a second gas manifold.

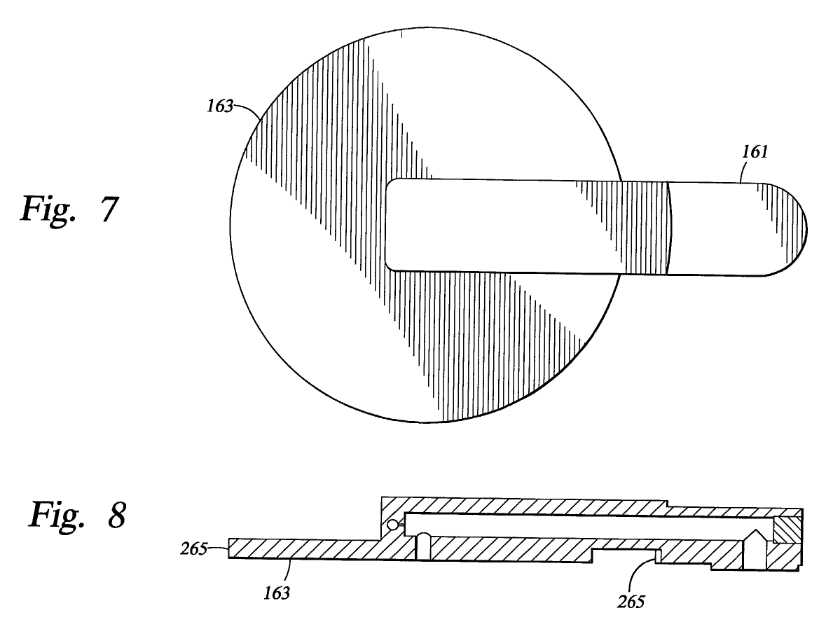

FIG. 7 is a top view of a gas manifold. An annular conductance restrictor plate 163 is mounted on the lower surface of the gas delivery block 161 (shown in FIG. 6) to mount the gas distribution plate 126 and prevent gas leakage at the interface between the gas manifold 146 and the gas distribution plate 126.

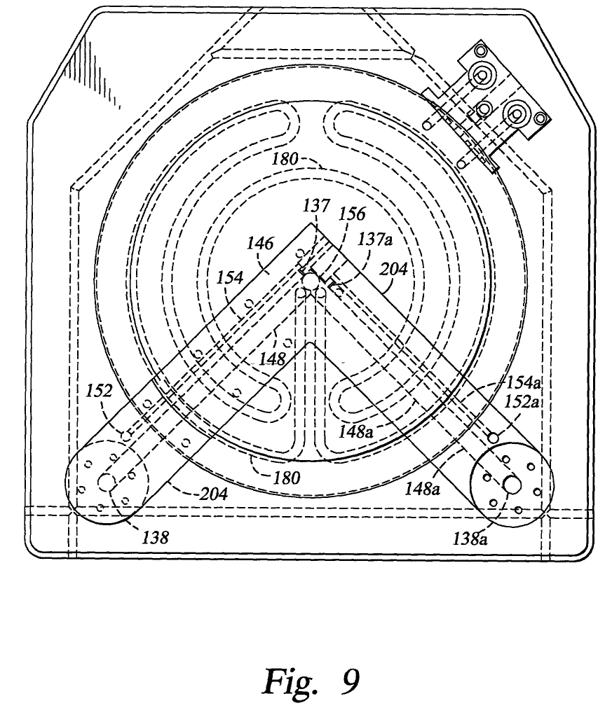

FIG. 8 is a cross sectional view of the gas manifold. The conductance restrictor plate 163 is sized and adapted to define an annular mounting recess 265 to which the gas distribution plate is secured.

FIG. 9 is a top view of a chamber lid showing an alternative embodiment of the gas manifold 146 that provides additional gas passages to allow further flexibility in the CVD chamber deposition schemes. The lower surface of the lid body defines two or more channels 204 for mounting a gas manifold 146. Two or more oxidizer gas passages 152, 152a are formed in the chamber body 112 for receiving an oxidizer gas delivery feedthrough which can be heated if desired to deliver one or more oxidizer gases through the chamber wall to the mixing gas manifold 146. Gas passages 154, 154a are formed in the mixing gas manifold 146 to deliver the oxidizer gas to a gas outlet 156, which provides a mixing point, located in the gas manifold adjacent the entry port into the gas distribution plate 126. Restrictive gas passages 137, 137a connect the oxidizer gas passages 154, 154a to the vaporized gas passages 148, 148a to provide high velocity delivery as well as mixing of the gas mixture upstream from the gas distribution plate 126.

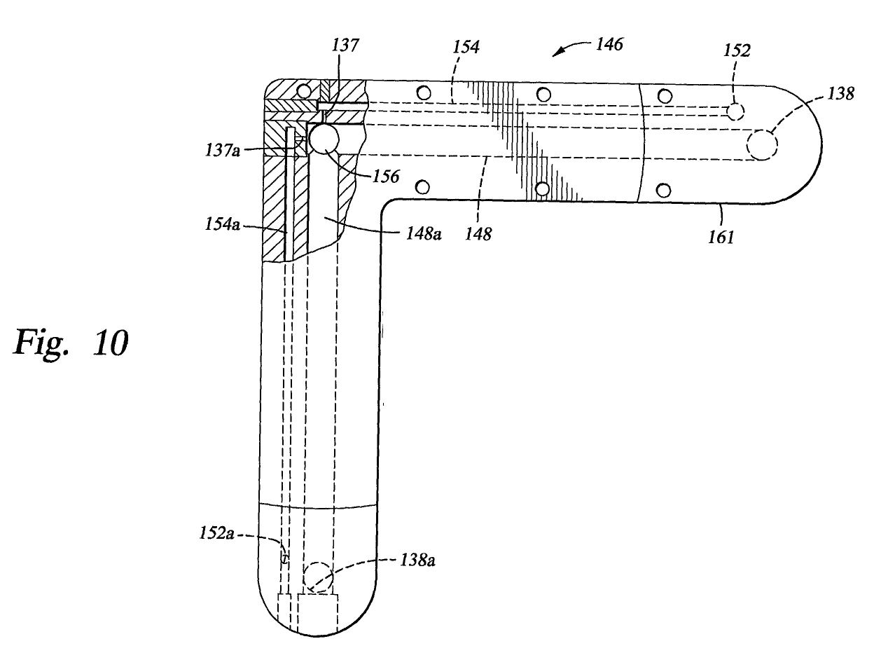

FIG. 10 is a partial cross sectional view of a gas manifold 146. The gas manifold 146 includes a gas delivery block 161 which defines two or more gas passages 148, 148a, 154, 154a therein having one or more gas inlets 138, 138a, 152, 152a on one end and a gas outlet 156 on the other end. The gas outlet 156 serves as a gas inlet of the gas distribution plate 126. Vaporized gas passages 148, 148a and oxidizer gas passages 154, 154a extend at least partially along the length of the gas manifold from the gas inlets to the gas outlet. Restrictive gas passages 137, 137a are disposed between the vaporized gas passages 148, 148a and the oxidizer gas passages 154, 154a, respectively, to optimally mix and deliver the oxidizer gas into the vaporized gas passage at a relatively high velocity to assist in mixing of the gases. The mixed gases are delivered through the gas outlet and to the blocker plate and face plate. Alternatively or additionally, additional vaporized gas passages and oxidizer gas passages, carrier gas passages or cleaning gas passages (to deliver a cleaning gas species from a remote plasma source) may also be provided through the chamber wall to deliver these gases to additional gas manifolds.

The embodiment shown in FIGS. 9 and 10 can, for example, allow controlled flow of the precursors near an endpoint of the flow path before deposition of the layers on the substrate. Such control can be advantageous when mixing multiple precursors that may require, for example, different vaporization temperatures and subsequent controlled temperatures along a flow path circuit from the vaporizer to the mixing point in the gas manifold. The mixtures can be tuned to a variety of percentages between the various components by controlling the flow rate through the various passages to allow flexibility. As another example, a first set of passages can be used to deposit a layer while flow through a second set of passages is stopped, and then flow through the first set stopped while flow through the second set occurs to deposit another layer of different material. The capability allows a variety of compatible layers to be deposited within the same chamber. Further, the various depositions of compatible layers could occur without removing the substrate from the chamber during the various process sequences and depositions.

Referring again to FIG. 2, the pumping system 118 includes a housing 208 mounted on the chamber. The housing 208 connects an exhaust passage and related pumps to the chamber and defines an internal gas passage (not shown) along its length. A pair of ports under the housing 208 are connected to a cold trap and exhaust pump and to a turbopump 218, or other high vacuum pump, with a gate valve 220 disposed therebetween. The turbopump enables the vacuum chamber to be evacuated down to a very low pressure to be compatible with processing platforms such as an Endura® platform available from Applied Materials, Inc. An exhaust pump such as a roughing pump, dry pump or other pump used in the industry is connected to the chamber at the exhaust port 214 in the nose to pump the chamber during processing. A cold trap 240 is disposed in the conduit connecting the exhaust pump to filter out the deposition material which may be detrimental to the pump. The cold trap is housed in a tubular housing 244 and includes a plurality of internal cooled passages for condensation of material thereon. Additionally, a second cold trap 242 is disposed below the first cold trap and is connected to a bypass line from the vaporizer. The bypass line and related cold trap allow the system to operate in a continuous flow made by allowing delivery of vaporized material thereto during wafer transfer.

A mounting plate 223 is mounted on the housing 208 and sealed thereto. The mounting plate can be removed to gain access to cartridge heaters and thermocouples disposed in the housing 208.

Liquid Delivery System

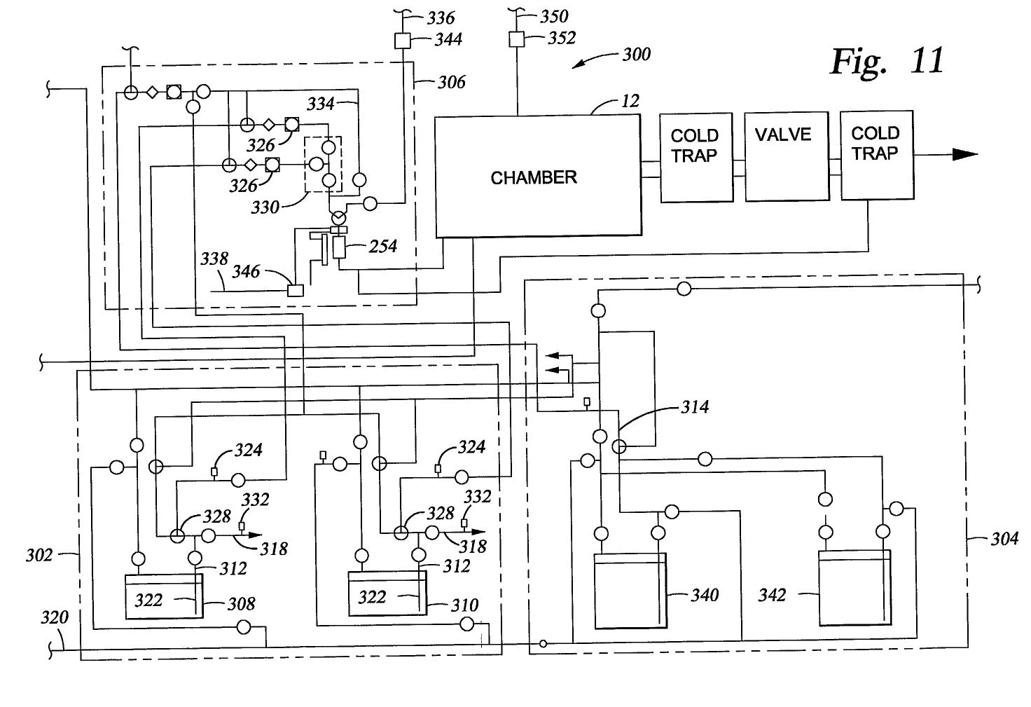

FIG. 11 is a schematic of a liquid delivery system 300. The liquid delivery system generally includes a liquid precursor module 302, a solvent module 304 and a vaporizer module 306. In one embodiment, the liquid precursor module 302 includes two pressurized ampoules 308, 310 and a liquid delivery line 312 connected to each ampoule. In other embodiments, the liquid precursor module 302 includes more than two pressurized ampoules and a liquid delivery line to supply, for example, the multiple gas passages in the gas manifold shown in FIGS. 9 and 10. Valves are disposed along the length of the liquid delivery lines to control flow of liquid from the ampoules to a mixing port and then into the vaporizer. Preferably, zero dead volume valves, which are described below, are used to prevent collection of precursor therein which can compromise the valves as well as negatively affect process stabilization and/or repeatability. The zero dead volume valves enable rapid flushing of precursor from the lines using solvent. Solvent is plumbed to the liquid delivery line 312 by line 314 to flush the system during maintenance. Additionally, a purge gas line is plumbed to the liquid delivery line to rapidly purge solvent from the line so that the system, including the ampoules, valves and/or LFCs, can be prepared for maintenance in about ten (10) to about thirty (30) minutes. The valving is designed so that when necessary, solvent can be introduced into the liquid delivery line upstream form the mixing port to flush the line through a bypass line 318 and out through a recovery system which includes a cold trap and exhaust manifold.

The ampoules are designed to deliver the liquid precursors at high pressure, e.g., up to 500 psi, without having to rely on high pressure pumps, i.e., no high cycle mechanical pump with rubbing parts exposed to precursors. To provide the pressure, an inert gas such as argon is charged into the ampoules at a pressure through line 320. A liquid outlet line 322 is disposed in the ampoule so that as the inert gas, e.g., argon, is delivered to the ampoule and the appropriate valves are opened, the liquid is forced out through the outlet through a suitable valve and into the liquid delivery line.

The liquid delivery line 312 is connected from each ampoule to the vaporizer. A first zero dead volume valve is disposed on the outlet of the ampoule to control delivery of the liquid to the delivery line 312. The valve is preferably a three-way valve connecting the bypass line 318 and the liquid delivery line 312. The bypass line 318 in turn is connected to a cold trap and an exhaust manifold (not shown). A high pressure gauge 324 and a LFC 326 are disposed downstream from a valve 328 introducing the solvent and the purge gas. The LFC controls delivery of the liquid to the mixing port 330 connected between the liquid precursor delivery lines. A low pressure gauge 332 is disposed on the bypass line 318 to monitor pressure in the line so that completion of the maintenance routine can be determined.

The liquid precursor delivery lines 312 deliver liquid precursors into the mixing port 330 upstream from the vaporizer 254. A solvent delivery line 334 also delivers a solvent into the liquid delivery line downstream from the mixing port where the liquid precursors and the solvent are mixed and delivered into the vaporizer. At the vaporizer, a carrier gas line 336 delivers a carrier gas, such as argon (herein Ar_{B}), into the delivery line to carry the liquid precursors and the solvent into the vaporizer through the capillary tube or nozzle. A mass flow controller (MFC) 344 controls the amount of gas in the carrier gas line 336. In addition, a concentric carrier gas line 338 delivers a carrier gas, such as argon (herein Ar_{A}), through a MFC 346 around the nozzle or injection tip of the vaporizer to ensure that even a small amount of liquid is delivered to the vaporizing surfaces. The delivery line from the mixing port and into the vaporizer is preferably made of a material having a low coefficient of friction, such as TEFLON® PTFE to reduce clogging in the line. The low coefficient of friction assists in the delivery of small volumes of liquid precursor. Additionally, a reactant gas, such as oxygen or hydrogen, is delivered through line 350 and through a MFC 353 into the chamber. Other gas lines can be used.

The solvent module 304 includes one or more chargeable ampoules similar to the liquid precursor ampoules. Preferably, there are at least two solvent ampoules 340, 342 and two liquid precursor ampoules 308, 310. The liquid precursor ampoules can deliver two separate precursors which can be mixed at the mixing port or can deliver the same precursor together or alternatively. Both the liquid precursor module 302 and the solvent module 304 can include additional ports and valves as optional stations for mounting additional ampoules for additional precursors.

The liquid precursor ampoules are designed with a slotted/sculptured bottom to draw the liquid downwardly in the ampoule so that the liquid may be detected at very low levels and drawn out of the ampoule even at low levels. Detection and delivery at low levels is particularly important in processing with expensive liquids to avoid waste. In addition, the ampoules include an ultrasonic detector for discerning the volume of liquid in the ampoule even at low levels so that continuous processing may be achieved.

Additionally, a single actuator valve is disposed on the outlets of the ampoules to control delivery of liquid precursor and to prevent clogging in the actuator. Also, the two way valves are preferably disposed on the downstream side of the liquid flow controllers in the vaporizer panel.

The delivery tubes are preferably made of a material such as TEFLON® to promote frictionless fluid flow therein to prevent clogging and deposition along the path of the tubes. It has been learned that TEFLON® provides a better conduit for materials such as the barium, strontium and titanium precursor liquids used in the deposition of BST.

The plumbing system is designed to enable rapid flushing of the lines and valves during routine maintenance. Additionally, the system is adapted to enable sequential shutdown of each of the valves as well as to deliver an automatic flush of a controlled amount of solvent through the vaporizer and the delivery lines in case of a power outage. This safety feature ensures that during uncontrolled power outages, the system will not be subject to clogging.

The delivery system may also comprise a bubbler system where a carrier gas such as argon can be bubbled through a solvent to suppress premature solvent evaporation from the precursor, thereby ensuring the precursor liquid will not be dried out en route to the vaporizer.

Liquid flow controllers (LFCs) and pisoelectric control valves, which can be disposed in situ to the system, are also used to maintain heightened control over the system. The high pressure gauges present on precursor and solvent lines as well as vacuum gauges on the vacuum manifolds are used to measure whether chemicals remain in the lines. These gauges are also used for onboard leak integrity measurements.

Multi-chamber System

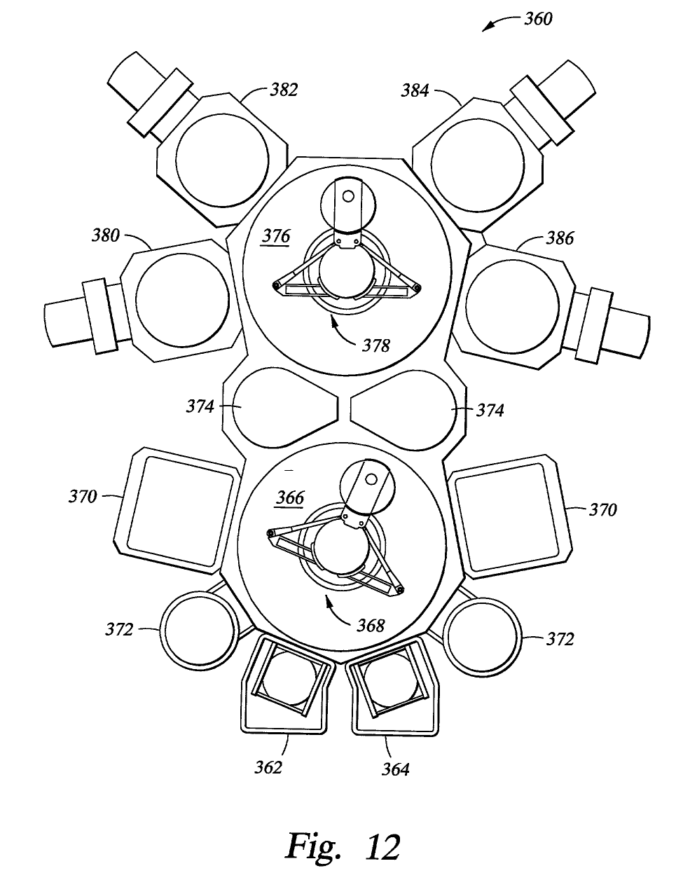

The PVD chamber and CVD chamber can be integrated into a multi-chamber system. FIG. 12 is a schematic view of a cluster tool system having multiple substrate processing chambers, such as an Endura® platform available from Applied Materials, Inc. The cluster tool system 360 includes vacuum load-lock chambers 362 and 364 attached to a first stage transfer chamber 366. The load-lock chambers 362 and 364 maintain vacuum conditions within the first stage transfer chamber 366 while substrates enter and exit system 360. A first robot 368 transfers substrates between the load-lock chambers 362 and 364 and one or more substrate processing chambers 370 and 372 attached to the first stage transfer chamber 366. Processing chambers 370 and 372 can be outfitted to perform a number of substrate processing operations such as CVD, PVD, etch, pre-clean, degas, orientation, anneal and other substrate processes. The first robot 368 also transfers substrates to/from one or more transfer chambers 374 disposed between the first stage transfer chamber 366 and a second stage transfer chamber 376.

The transfer chambers 374 are used to maintain ultrahigh vacuum conditions in the second stage transfer chamber 376 while allowing substrates to be transferred between the first stage transfer chamber 366 and the second stage transfer chamber 376. A second robot 378 transfers substrates between the transfer chambers 374 and a plurality of substrate processing chambers 380, 382, 384 and 386. Similar to processing chambers 370 and 372, the processing chambers 380 to 386 can be outfitted to perform a variety of substrate processing operations. For example, the processing chamber 380 is a PVD chamber outfitted to deposit a platinum nucleation layer or other HDC compatible material, the processing chamber 382 is a CVD chamber outfitted to deposit a platinum bulk material on the nucleation layer, the processing chamber 384 is an etching chamber outfitted to etch apertures or opening for interconnect features and the processing chamber 386 is a CVD chamber outfitted to deposit an HDC material, such as BST, on the platinum layer. The CVD processing chamber 382 or another chamber can be used to deposit another conductive layer on the HDC material.

Also, at least one of the processing chambers 370 or another processing chamber can be an anneal chamber outfitted to anneal deposited material from other processing chambers. An anneal chamber is used to heat the substrate and lower the surface roughness of the particular layer being annealed. Preferably, the conductive HDC compatible material, such as a platinum layer, is annealed prior to depositing the HDC material thereon. The anneal chamber can be a standard DxZ chamber with the heater therein, available from Applied Materials, Inc. Other chambers could be used such as a chamber having a heated plate above the substrate to radiate heat therefrom. Further, other annealing processes can be used such as rapid thermal anneal (RTP) or heating by microwaves to anneal the substrate and layers thereon. A gas, such as oxygen or nitrogen, is preferably flown into the chamber during the anneal process. The gas assists in reacting with free carbon in the substrate and purging the carbon from the substrate.

The above listed sequence arrangement of the processing chambers is useful for practicing aspects of the present invention. A plurality of cluster tool systems may be required to perform all of the processes required to complete manufacturing of an integrated circuit or chip.

During operation, substrates are brought to vacuum load-lock chambers 362 and 364 by a conveyor belt or robot system (not shown) that operates under the control of a computer program executed by a microprocessor or computer (not shown). Also, the robots 368 and 378 operate under control of the computer program to transfer substrates between the various processing chambers of the cluster tool system 360.

The above-described cluster tool system is mainly for illustrative purposes. Other plasma processing equipment, such as electron cyclotron resonance (ECR) plasma processing devices, induction-coupled RF high-density plasma processing devices or the like may be employed as part of the cluster tool system.

Exemplary Structure

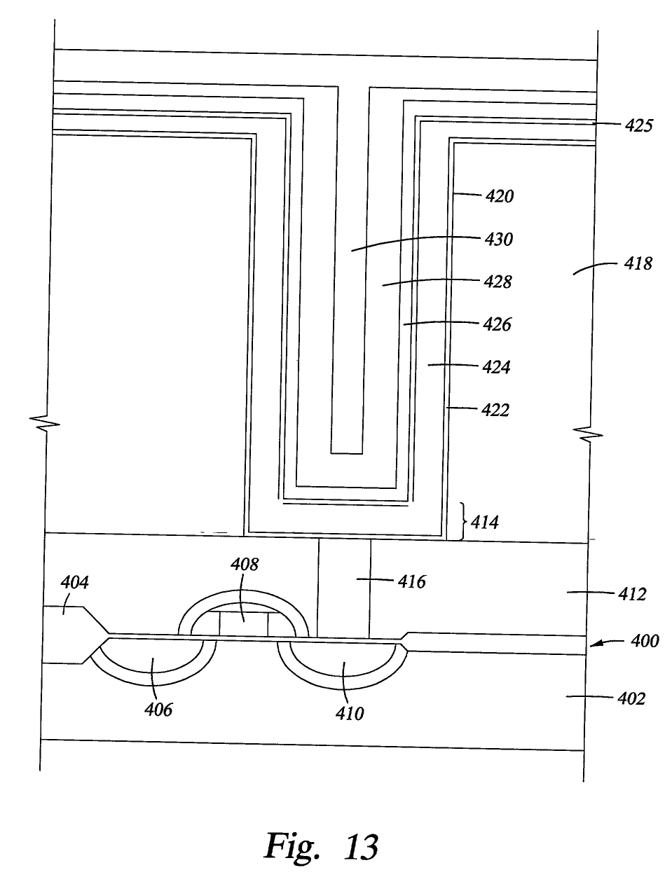

FIG. 13 is a schematic cross sectional view of a portion of a substrate having a stack 400 of layers formed thereon. The substrate 402, generally made of silicon material, comprises a doped source region 406, a gate region 408 and a drain region 410 that connect various transistors, such as transistor 404, to features in the structure such as contacts, vias, trenches and lines. A premetal dielectric layer 412, such as a silicon-based oxide, is deposited on the substrate 402 and separates the substrate from the conductive layer 414. A feature is etched in the silicon based oxide and then filled to form a contact 416, such as a tungsten contact between the drain region 410 and the conductive layer 414. Another dielectric layer 418, such as a silicon-based oxide, is deposited over the contact 416. Another feature 420, such as a trench or via, is etched in the dielectric layer 418. A nucleation layer 422, such as a platinum nucleation layer, is deposited on the feature, preferably by a sputtering process. The substrate is preferably moved to a CVD chamber and a conductive material, such as platinum, is deposited by CVD on the nucleation layer 422 to form a conductive layer 424. Another nucleation layer 425 can be deposited on the conductive layer 424 that is compatible with a subsequent deposition of HDC material. The nucleation layer 425 can be formed by, for example, CVD. The HDC material, such as BST, can be deposited on the nucleation layer 425 to form a dielectric layer 426 and can also be deposited by CVD. Alternatively, the HDC material can be deposited directly on the conductive layer 424 in the absence of the nucleation layer 425. Another conductive layer 428, such as a platinum layer, is deposited, preferably by CVD on the dielectric layer 426. Another dielectric layer 430 is deposited on the conductive layer 428 to fill the remainder of the feature 420. Additional conductive layers and dielectric layers (not shown) can be deposited to form the stack 400. Further, a planarized passivation layer (not shown) can be deposited over the several layers.

Exemplary PVD Process for a Nucleation Layer of Conductive HDC Compatible Materials

An exemplary process regime for depositing a conductive HDC compatible material, such as platinum, is as follows for a 200 mm wafer in a PVD chamber, such as described in reference to FIG. 1. An inert gas, such as helium or argon, is flown into the chamber at a rate sufficient to produce a chamber pressure of about 5 to about 100 mTorr, preferably about 20 mTorr to about 50 mTorr and most preferably about 30 mTorr. The power supply 52 delivers about 200 watts (W) to about 6 kW, preferably about 0.75 kW to about 1.5 kW and most preferably about 1 kW, to a platinum target 4. The bias between the target and the substrate creates a plasma of ionized ions therebetween. The ions are attracted to the relatively negative biased target, impact the target and dislodge sputtered particles of platinum from the target. Some of the sputtered particles are directed toward the substrate and are deposited thereon. The substrate is maintained at a temperature between about 10° C. and about 400° C., preferably below 300° C. Preferably, platinum is deposited on the substrate to a thickness of less than about 50 Å to about 200 Å to establish a nucleation layer.

Other materials can be used to deposit a nucleation layer as long as the materials are compatible with the subsequent conductive material deposited thereon. For example, such conductive HDC compatible materials include platinum, ruthenium, iridium, rhodium, platinum combined with rhodium, platinum combined with iridium, platinum combined with ruthenium, strontium ruthenate (SRO), lanthanum strontium cobalt oxide (LSCO), yttrium barium copper oxide (YBCO) and combinations thereof.

Exemplary CVD Process for Conductive HDC Compatible Materials

Once the nucleation layer is deposited on the substrate, the substrate is moved to a CVD chamber such as shown in FIG. 2. A bulk deposition of a suitable conductive HDC compatible material can then be carried out to deposit the conductive HDC compatible material on the sputtered nucleation layer. For example, a bulk deposition of platinum can made on the PVD platinum nucleation layer. One exemplary process for CVD platinum on a 200 mm wafer mounted on a heated substrate holder is described below. The deposition occurs at about 1 Torr to about 5 Torr and preferably between about 2 Torr to about 3 Torr. The wafer temperature is between about 150° C. to about 600° C. and preferably between about 300° C. to about 425° C. A compound containing platinum, such as (methylcyclopentadienyl)trimethylplatinum, (MeCp)Pt(Me)₃, can have a flow rate between about 0 milligrams per minute (mg/m) to about 500 mg/m. Preferably, a flow rate of about 400 mg/m to about 500 mg/m is used. Molarity of the platinum solution can range between about 0.05 M to about 2.5 M and preferably about 0.1 M to about 1 M. Oxygen can be flown into the CVD chamber at a rate of between about 100 standard cubic centimeters per minute (sccm) to about 5000 sccm with a preferable rate of between about 400 to 5000 sccm. An inert gas, such as argon (herein Ar_{A}), can be flown around the vaporizer nozzle to stabilize the droplets sprayed from the nozzle at a rate of about 100 to about 150 sccm with a preferably rate of about 120 sccm to about 140 sccm. The vaporizer for the precursors can be maintained at about 50° C. to about 80° C. A carrier gas, such as argon (herein ArB), can be flown into the chamber to stabilize the process at a rate of between about 100 sccm to 1000 sccm and preferably about 200 sccm to about 300 sccm.

Annealing of the deposited platinum CVD layer is performed at a temperature of about 500° C. to about 700° C. It is preferable to anneal at least the PVD layer so that the structure is better stabilized and has lower film stress and smoother surface roughness. Subsequent layers can also be annealed at an appropriate temperature depending on the material deposited.

Exemplary Deposition of HDC Materials

Exemplary HDC layers which can be deposited using the present system may include tantalum pentoxide (Ta₂O₅), a zirconate titanate (ZrxTiyOz), strontium titanate (SrTiO₃), barium strontium titanate (BST), lead zirconate titanate (PZT), lanthanum-doped PZT, bismuth titanate (Bi₄Ti₃O₁₂), barium titanate (BaTiO₃), or the like. Other materials which can be deposited include those materials having a narrow range between vaporization and decomposition.

Substrate 402 used in the present invention can include primarily P-type and N-type silicon. Depending on the particular process chemistry and desired end product, other substrate materials may be usable, including other semiconductors, e.g., germanium, diamond, compound semiconductors, e.g., GaAs, InP, Si/Ge, SiC, and ceramics.

The selection of materials for the layers above the substrate 402 in an integrated circuit structure 400 depends on the device that is formed and other layers that a particular layer currently or subsequently contacts. Devices that can be made with the present system include, but are not limited to, 64 Mbit, 256 Mbit, 1 Gbit and 4 Gbit DRAMs. The system also has particular application with other liquid precursors which are volatile as well as materials such as copper.

BST Process

The vapor desired for use in the deposition process can be a mix of a first and a second vaporized liquid precursor combined in predetermined mass or molar proportions. For use in deposition of BST, the first liquid precursor is preferably one of a mixture of Ba and Sr polyamine compounds in a suitable solvent such as butyl acetate. Some preferred mixtures combine bis(tetra methyl heptandionate) barium penta methyl diethylene triamine, commonly known as Ba PMDET (tmhd)₂, and bis(tetra methyl heptandionate) strontium penta methyl diethylene triamine, commonly known as Sr PMDET (tmhd)₂, or, in the alternative, bis(tetra methyl heptandionate) barium tetraglyme, commonly known as Ba (tmhd)₂ tetraglyme, and bis(tetra methyl heptandionate) strontium tetraglyme, commonly known as Sr (tmhd)₂ tetraglyme. The second liquid precursor is preferably bis(tetra methyl heptandionate) bis isopropanide titanium, commonly known as Ti (I-pr-o)(tmhd)₂, or other titanium metal organic sources, such as Ti(tBuO)₂(tmhd)₂. The molar ratio between the combined metals in the first liquid precursor and the second liquid precursor is preferably about 2:1:4 Ba:Sr:Ti. The molar ratio can vary from about 2:1:2 to about 2:1:8. Other precursors that could be used include precursors without the penta methyl diethylene triamine (PMDET) component. A suitable solvent for such precursors could be tetrahydrofuran (THF).

The BST process mixes the vaporized first and second liquid precursors with an oxidizing gas such as oxygen, N₂O, O₃ or combinations thereof, at a temperature above the vaporization temperature of the precursors and below a temperature which degrades the components. The process is very sensitive to changes in temperature of the substrate, solvent content of the liquid precursors, and concentration of the oxidizer in the combined gases. In general, increasing the wafer temperature increases the deposition rate, reducing the solvent content of the liquid precursors reduces the haze of the films, and controlling the oxidizer flow rate controls the roughness of the film and crystalline phase.

### EXAMPLE 1

One exemplary process deposited a BST film on a 200 mm wafer mounted on a heated substrate holder spaced 550 mils from a gas distribution showerhead or face plate. The deposition occured at 1.7 Torr with a wafer temperature of 600□C. and the following flow rates. The first precursor was 33 mg/min to 200 mg/min of a mixture of Ba PMDET (tmhd)₂ and Sr PMDET (tmhd)₂ in butyl acetate having a molar ratio of Ba:Sr of 2:1. The second precursor was 17 mg/min to 77 mg/min of Ti (I-pr-o) (tmhd)₂ in butyl acetate which provides a molar ratio of Ba:Sr:Ti of 2:1:4. The substrate was a Pt/SiO₂/Si. A deposition rate of 40 to 160 Å/minute was achieved using process gas flow rate of 2900 sccm (that is, a combination of O₂ at 500 sccm, N₂O at 500 sccm, Ar_{A} at 1500 sccm, and Ar_{B} at approximately 900 sccm). A vaporizer was also used, where the vaporizer lines for the precursors were maintained at 240° C.

### EXAMPLE 2

Another exemplary process deposited a BST film on a 200 mm wafer mounted on a heated substrate holder spaced 550 mils from a gas distribution showerhead. The deposition occured at 7 Torr with a heater temperature of about 680□C. and the following flow rates. The first precursor was 33 mg/min to 200 mg/min of a mixture of Ba PMDET (tmhd)₂ and Sr PMDET (tmhd)₂ in butyl acetate having a molar ratio of Ba:Sr of 2:1. The second precursor was 17 mg/min to 77 mg/min of Ti (I-pr-o) (tmhd)₂ in butyl acetate which provides a molar ratio of Ba:Sr:Ti of 2:1:4. The substrate was a Pt/SiO₂/Si. A deposition rate of 151 Å/minute was achieved using process gas flow rate of 1300 sccm (that is, a combination of O₂ at 250 sccm, N₂O at 250 sccm, Ar_{A} at 500 sccm, and Ar_{B} at approximately 300 sccm). A vaporizer was also used, where the vaporizer lines for the precursors were maintained at 240° C. A two mixture process showed repeatable results over a twenty five wafer run.

### EXAMPLE 3

In another example, the system was cleaned using acetone as a solvent. The acetone used was not dried. A deposition process according to that described in Example 1 was then performed. A 2× increase in the deposition rate was observed, indicating that residual acetone solvent stabilized the precursors on delivery to the substrate and consequently resulted in the higher deposition rate. It is believed that the acetone stabilizes the precursors through hydrogen bonding so that more precursor is delivered to the substrate surface for reaction.

### EXAMPLE 4

It is believed that use of a solvent such as acetone during the deposition process will stabilize the precursors and result in a higher deposition rate.

The above structures can be varied for example by depositing a barrier layer below the conductive HDC compatible material. A barrier layer(s) can be formed from a material such as titanium (Ti), titanium nitride (TiN), titanium aluminum nitride (TiAlN), tantalum (Ta), tantalum nitride (TaN), tantalum aluminum nitride (TaAlN) and combinations thereof.

While the foregoing is directed to an embodiment of the invention, other and further embodiments of the invention may be devised without departing from the basic scope thereof, and the scope thereof is determined by the claims which follow.

1. A system for processing substrates, comprising:
a) a vacuum chamber;
b) a physical vapor deposition (PVD) chamber in communication with the vacuum chamber; and
c) a chemical vapor deposition chamber (CVD) including a gas manifold having at least two sets of passages, each set including at least a vaporized gas passage, the CVD chamber being in communication with the vacuum chamber.

2. The system of claim 1, wherein each set of passages in the gas manifold comprises an oxidizer passage.

3. The system of claim 1, further comprising a liquid delivery system comprising a plurality of liquid precursor ampoules.

4. The system of claim 1, further comprising a target disposed in the PVD chamber, at least a portion of the target comprising a conductive high-dielectric-constant (HDC) compatible material.

5. The system of claim 4, wherein the conductive high-dielectric-constant (HDC) compatible material comprises at least platinum, ruthenium, iridium, rhodium, platinum combined with rhodium, platinum combined with iridium, platinum combined with ruthenium, strontium ruthenate (SRO), lanthanum strontium cobalt oxide (LSCO), yttrium barium copper oxide (YBCO) and combinations thereof.

6. The system of claim 5, wherein the HDC material comprises at least tantalum pentoxide (Ta₂O₅), a zirconate titanate (ZrₓTi_{y}O_{z}), strontium titanate (SrTiO₃), barium strontium titanate (BST), lead zirconate titanate (PZT), lanthanum-doped PZT, bismuth titanate (Bi₄Ti₃O₁₂), barium titanate (BaTiO₃) or combinations thereof.

7. The system of claim 1, further comprising an annealing chamber in communication with the vacuum enclosure.

8. A chamber for processing substrates, comprising:
a) an enclosure having a top, bottom and sides;
b) a substrate support disposed in the enclosure; and
c) a gas manifold disposed above the substrate support, the gas manifold having at least two sets of passages, each set including an oxidizer passage and a vaporized gas passage.

9. The chamber of claim 8, wherein the gas manifold delivers both a conductive HDC compatible material gas and an HDC material gas to the enclosure.

10. A method of depositing multiple layers on a substrate in a processing system, comprising:
a) sputter depositing a first nucleating layer on the substrate;
b) depositing by chemical vapor deposition (CVD) a conductive high-dielectric-constant (HDC) compatible material on the first nucleating layer; and
c) depositing an HDC material on the conductive HDC compatible material by CVD.

11. The method of claim 10, wherein the conductive HDC compatible material comprises platinum, ruthenium, iridium, rhodium, platinum combined with rhodium, platinum combined with iridium, platinum combined with ruthenium, strontium ruthenate (SRO), lanthanum strontium cobalt oxide (LSCO), yttrium barium copper oxide (YBCO) and combinations thereof.

12. The method of claim 10, wherein the HDC material comprises tantalum pentoxide (Ta₂O₅), a zirconate titanate (ZrₓTi_{y}O_{z}), strontium titanate (SrTiO₃), barium strontium titanate (BST), lead zirconate titanate (PZT), lanthanum-doped PZT, bismuth titanate (Bi₄Ti₃O₁₂), barium titanate (BaTiO₃) or combinations thereof.

13. The method of claim 10, further comprising annealing at least the CVD layer of the conductive HDC compatible material.

14. The method of claim 10, further comprising in situ depositing the CVD layer of the conductive HDC compatible material and the CVD layer of the HDC material.

15. The method of claim 14, further comprising vaporizing multiple liquids in at least one vaporizer and flowing the vaporized liquids to a gas manifold in communication with a chamber in the processing system.

16. The method of claim 10, wherein the PVD and CVD layers are deposited in chambers in communication with a centralized vacuum chamber in the processing system.

17. The method of claim 10, further comprising controlling a substrate support temperature supporting the substrate during the CVD deposition of the conductive HDC compatible material from about 300° C. to about 425° C.

18. The method of claim 10, further comprising controlling an oxygen flow rate into a CVD chamber in the system during the CVD deposition of the conductive HDC compatible material to greater than about 400 standard cubic centimeters per minute (sccm).

19. The method of claim 10, further comprising depositing a barrier layer on the substrate prior to the depositing the first nucleating layer.

20. The method of claim 10, further comprising depositing a second nucleating layer prior to depositing the HDC material.

21. The method of claim 10, further comprising depositing a conductive material to form a conductive layer on the HDC material.

22. A substrate having layers formed thereon, comprising:
a) a sputtered nucleating layer deposited directly on a substrate that is compatible with a high-dielectric-constant (HDC) material;
b) a layer of the conductive HDC compatible material deposited on the nucleating layer by chemical vapor deposition (CVD); and
c) a layer of an HDC material deposited on the conductive HDC compatible layer by CVD.

23. The substrate of claim 22, wherein at least the conductive HDC compatible layer is annealed prior to the HDC layer deposited thereon.

24. The substrate of claim 22, wherein the conductive HDC compatible layer is deposited in the same chamber as the HDC layer.

25. The substrate of claim 22, wherein the conductive HDC compatible material comprises platinum, ruthenium, iridium, rhodium, platinum combined with rhodium, platinum combined with iridium, platinum combined with ruthenium, strontium ruthenate (SRO), lanthanum strontium cobalt oxide (LSCO), yttrium barium copper oxide (YBCO) and combinations thereof.

26. The substrate of claim 22, wherein the HDC material comprises tantalum pentoxide (Ta₂O₅), a zirconate titanate (ZrₓTi_{y}O_{z}), strontium titanate (SrTiO₃), barium strontium titanate (BST), lead zirconate titanate (PZT), lanthanum-doped PZT, bismuth titanate (Bi₄Ti₃O₁₂), barium titanate (BaTiO₃) or combinations thereof.
